(19) United States
(12) Patent Application Publication
(10) Pub. No.: US 2014/0261971 A1
(43) Pub. Date: Sep. 18, 2014

(54) Method of manufacturing Multilayer Piezoelectric Devices

(71) Applicant: Solid State Ceramics, Inc.., Williamsport, PA (US)

(72) Inventors: Safakcan Truncdemir, State College, PA (US); Ross Bird, Canton, PA (US); Gareth Knowles, Williamsport, PA (US)

(73) Assignee: SOLID STATE CERAMICS, INC., Williamsport, PA (US)

(21) Appl. No.: 14/215,050

(22) Filed: Mar. 16, 2014

Related U.S. Application Data
(60) Provisional application No. 61/790,745, filed on Mar. 15, 2013.

(51) Int. Cl. H01L 41/277

(52) U.S. Cl. CPC H01L 41/277
USPC 156/89.12

(57) ABSTRACT

A process that permits existing thick film printing technology to be utilized with existing conductive adhesives to form multi-layer dielectric devices, more specifically to form multi-layer ferroelectric devices, and more specifically to form multilayer piezoelectric devices. A conductive paste is applied to a first surface of a piezoelectric element in a desired pattern. The disclosed process utilizes conductive paste, which replaces the usual adhesive requirement for bonding while still acting as the conductive layer between the individual elements of the stacked sintered substrates. An isolating filler paste is applied to the first surface of the piezoelectric element in a manner that electrically isolates the conductive pattern as to enable multiple distinct, possibly unequal, regions of electric potential. This paste also may assist bonding and will prevent shorting between the electrically non-equivalent regions of the overall electrode pattern. Multiple substrates are stacked, dried and fired as described herein to form multilayer piezoelectric devices.

This application claims the benefit of U.S. provisional Application Ser. No. 61/790,745, filed Mar. 15, 2013, which is hereby incorporated by reference.

### FIELD OF THE INVENTION

The present invention is related to a method of manufacturing multilayer devices. More particularly, this invention is related to a method of manufacturing multilayer piezoelectric devices.

### BACKGROUND

There are two main types of manufacturing processes generally available for producing multilayered ceramic devices, ‘cut-and-bond’ methods (also referred to as ‘stack-type’ methods), and ‘tape-casting’ methods (also referred to as ‘co-fired-type’ methods).

‘Cut-and-bond’ methods basically involve cutting, polishing and electroding (e.g., electrode printing, drying at around 120° C., and firing at around 600° C.) several individual layers from pre-sintered bulk material, stacking the individual layers, and bonding the layers to form a multilayer device. Bonding typically involves applying an adhesive at each bonding layer.

Adhesives are known for having a tendency to dampen vibration and contribute to elastic and dielectric losses at high frequency vibration, thereby worsening the output/input energy efficiency of the multilayer device. Heat generation as a result of the aforementioned dielectric losses can also adversely increase the temperature of the device to levels above that which is needed to be maintained in order to ensure material and bonding integrity of the device.

The above-described problems associated with devices produced by ‘cut-and-bond’ methods become more exaggerated and critical as the layer count of the stack is increased.

The second manufacturing process, ‘tape-casting’, generally involves tape casting individual green sheets, which are subsequently electroded, laminated, and sintered. Steps in a ‘tape-casting’ process can include, but are not limited to, preparing a slurry, slip casting to form individual green sheets, electrode printing, drying, lamination, cutting, and firing. As such, electrode printed ceramic green sheets, or tapes, are laminated prior to firing the ceramic and electrode materials together, thereby eliminating the need for adhesive layer bonding.

‘Tape-casting’ methods are generally more suitable for mass production of multilayered ceramic device, as compared to ‘cut-and-bond’ methods. ‘Tape-casting’ also allows for higher layer counts and thinner ceramic layers, which reduce drive voltages. However, ‘tape-casting’ methods also typically require more expensive equipment and intricate techniques than ‘cut-and-bond’ methods. Therefore, what is needed are methods for producing multilayer ceramic devices which overcome the above-described difficulties, and are capable of producing multilayered devices having a greater number of layers with improved thermal integrity, mechanical integrity, and overall electrical properties.

### SUMMARY

A method of manufacturing a multilayer piezoelectric device includes forming a pattern of conductive paste on a surface of a first piezoelectric element. Isolating filler paste is applied to the surface of the piezoelectric element in a complementary pattern to the pattern of conductive paste, such that substantially all of a surface area of the first piezoelectric element is covered by the isolating filler and the conductive paste. The method also includes drying the piezoelectric element with the applied isolating filler paste and the conductive filler paste. A second piezoelectric element is stacked onto the first piezoelectric element such that a blank surface of the second piezoelectric element contacts the dried filler paste and conductive paste of the first piezoelectric element, thereby forming a stacked structure. The stacked structure is fired for a sufficient time at a firing temperature that is sufficient to evaporate carriers and plasticizers present in the isolating and conductive pastes. The stacked structure is then polarized.

A method of manufacturing a multilayer includes forming a pattern of conductive paste on a surface of a first piezoelectric element. The first piezoelectric element is dried with the applied conductive paste. An isolating filler paste is applied to the surface of the dried first piezoelectric element in a complementary pattern to the pattern of conductive paste, such that substantially all of a surface area of the first piezoelectric element is covered by the isolating filler paste. The first piezoelectric element with the applied isolating filler paste is then dried. . A second piezoelectric element is stacked onto the first piezoelectric element such that a blank surface of the second piezoelectric element contacts the dried filler paste and conductive paste of the first piezoelectric element, thereby forming a stacked structure. The stacked structure is fired for a sufficient time at a firing temperature that is sufficient to evaporate carriers and plasticizers present in the isolating and conductive pastes. The stacked structure is then polarized.

### BRIEF DESCRIPTION OF THE DRAWINGS

FIG. 1 depicts a multilayer manufacturing process in accordance with an embodiment of the invention.

FIG. 2 depicts a multilayer manufacturing process in accordance with another embodiment of the invention.

FIG. 3a depicts an embodiment of a stacked multilayer device in accordance with the invention.

FIG. 3b depicts an embodiment of a stacked multilayer device in accordance with the invention.

FIG. 3c depicts an embodiment of a stacked multilayer device in accordance with the invention.

### DESCRIPTION OF THE EMBODIMENTS OF THE INVENTION

The present invention is directed to methods of manufacturing multilayer piezoelectric devices.

As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus.

As used herein, and unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” are employed to describe elements and components described herein. This is done merely for convenience and to give a general sense of the scope of the invention. This description should be read to include one or at least one and the singular also includes the plural unless it is obvious that it is meant otherwise.

Further, references to values stated in ranges include each and every value within that range. Thus, to the maximum extent allowed by law, the scope of the present invention is to be determined by the broadest permissible interpretation of the following claims and their equivalents, and shall not be restricted or limited by the foregoing detailed description.

Various embodiments of the present disclosure will now be described, by way of example only, with reference to the accompanying drawings.

FIG. 1 depicts a method in of making multilayer piezoelectric devices in accordance with an embodiment of the invention, this method sometimes being referred to as “co-bonding”. In step A, piezoelectric elements 41, in some embodiments piezoelectric ceramics, are sintered, cut, and polished to meet desired dimensions. The surfaces of the piezoelectric elements 41 may be prepared for stacking by removing the foreign agents, which may prevent proper wetting, and bonding ability of bonding agents. A sintered piezoelectric ceramic element may be obtained by sintering piezoceramic pressed powder.

In step B electrode pattern 42 made of from conductive paste is laid down on the surface of the piezoelectric element 41 by, e.g., thick film printing methods such as screen-printing such that the conductive paste has a given print thickness. In accordance with an exemplary embodiment, the print thickness of the conductive paste is between about 40 μm and 10 μm, and, in some embodiments, on the order of about 25 μm. Conductive pastes generally have three ingredients: a binder, e.g., glass frit; a vehicle, e.g., organic solvent and plasticizer; and a host material, e.g., a metal. In keeping with the invention, host materials include, but are not limited to, precious metals such as Ag, Au, Pt, Pd as well as alloys such as Ag—Pd, Au—Pt, or Au—Pd. These materials may further include refractory metals such as Mo and Tu and/or non-precious metals such as Cu, Ni. The choice of conductive paste depends on the firing temperature, the interaction of the host material and the adherend, i.e., piezoelectric element 41, the surface quality of piezoelectric element 41 and fabrication conditions. Other methods of applying the conductive paste can include spray coating, dip or brush coating, pad printing, and vapor deposition. In at least one embodiment, using a silk screening process, the conductive paste may be applied to the piezoelectric elements through metal masks to form patterns 42.

In step C an isolating filler material made of from a high dielectric, low electrical conduction material which may include a glass paste, an overglaze or similar material, is laid down on the surface of the piezoelectric element 41 in a pattern 43 that complements electrode pattern 42 using similar methods employed to lay down electrode pattern 42. In keeping with the invention, the isolating filler material is used to isolate electrode sections of electrode pattern 42 from each other thereby allowing different electrode sections of the electrode pattern 42 to carry different potentials. This characteristic is particularly useful in devices such as piezoelectric transformers which often have complex electrode patterns. The print thickness of the isolating filler material is close to or matches the print thickness of the conductive paste. That is, the print thickness of the isolating filler material may be within ±15% of the print thickness of the conductive paste. In accordance with an exemplary embodiment, the print thickness of the isolating material is between about 40 μm and 10 μm, and, in some embodiments, on the order of about 30 μm.

A suitable isolation filler material contains a glass frit, an organic solvent and a plasticizer similar to the conductive paste. However, in keeping with the invention, the suitable isolation material does not contain a conducting metal host thereby allowing the isolation material to act as a sealant or isolator once dried and fired.

A suitable isolation filler material should exhibit one or more of the characteristics described herein. For example, a suitable isolation material should have good adhesion with piezoelectric element 41 and the conductive paste. That is, isolation filler material should have a Peel strength on the order of at least about 75 to 100 lb/in² (0.52 N/mm² to 0.69 N/mm²).

The isolation filler material should also exhibit very slow diffusion into the conductive paste before the isolation filler material and the conductive paste transform into a glass phase and little or no diffusion into the conductive paste after the glass phase.

The isolation filler material may also have a high resistance, e.g., larger than 10 Giga-ohm at 100 VDC, and a high dielectric value with high dielectric breakdown values.

A suitable isolation filler material may also have a thermal expansion coefficient that is within at least about ±20% of the thermal expansion coefficient of (i) the conductive paste and (ii) the piezoelectric element 41.

In step D the conductive paste and complementing isolating material patterns are dried by evaporating the organic solvents and plasticizers that may outgas in later steps to produce dried conductive paste pattern 44 and dried isolating material pattern 45. The typical range of drying temperature is between 120° C. and 160° C. and the typical range of time for drying is between 5 to 15 minutes. In an exemplary embodiment the drying temperature is about 150° C. and the drying time is about 10 minutes.

In step E piezoelectric elements 41 dried as described in step D are aligned and stacked under sufficient pressure to ensure effective surface contact between the dried pastes and the contact surface of the piezoelectric element. As illustrated in FIG. 4, the piezoelectric elements 41 are stacked such that a blank surface of a first piezoelectric element is directly pressed against dried conductive paste pattern 44 and dried isolating material pattern 45 of a second piezoelectric element 41 thereby forming a multilayer piezoelectric assembly 60.

In step F the piezoelectric assembly 60 is fired at elevated temperatures to evaporate and to burn the plasticizers and other carriers that may be present in the dried isolating material and the dried conductive paste. Firing temperatures and firing profiles depends on the material properties, which are identified by the manufacturers. The firing temperature should be selected to stay below the original sintering temperature of the piezoelectric element 41 and below the melting point of the host metal of the conducting paste. Typical firing temperature range for an Ag—Pd conductive paste is between 500° C. and 570° C., and most typically 560° C. Typical firing duration for the Ag—Pd conductive paste is 60 minutes. As a result, fired electrodes 46 and cured glass filler 47 in designed shapes specific to the applications are bonded between the piezoelectric elements 41 forming a fired multilayer piezoelectric structure 65. In some embodiments the multilayer piezoelectric assembly 60 is fired while under pressure. In an exemplary embodiment, the fired thickness of the conductive paste and the isolating material are within about ±20% of each other. For example, the conductive paste may have a fired thickness of about 15 μm and the isolation filler material may have a fired thickness of about 18 μm. An exemplary suitable conductive paste is ESL 599-G conductive paste and a suitable exemplary isolation filler material is ESL 4031-B glass paste both available from ESL Electro Science of King of Prussia, Pa.

In some embodiments, the multilayer piezoelectric structure 65 may be cooled to approximately room. In an embodiment, the pressure applied in stacking step E may be maintained during firing and/or cooling. In accordance with other embodiments, the pressure applied during stacking step E may be relieved prior to firing or prior to cooling. After cooling, a voltage may be applied to the piezoelectric structure 65 at a temperature of about half of the Curie Point of the piezoelectric element to effect polarization. As used herein, the term “Curie Point” refers to the temperature at which the piezoelectric element loses its characteristic properties.

FIG. 2 shows the variation of the process shown in FIG. 1, where the conductive paste and isolating material are dried separately. In FIG. 2, the isolating filler material is laid down after the conducting paste has been dried. The isolating filler material is subsequently dried. In contrast, in FIG. 1, the isolating filler material and the conductive paste are dried simultaneously.

FIGS. 3a, 3b and 3c are preferred embodiments showing bonding surfaces where the methods described herein can be applied to obtain stacks in various geometries. The conductive and isolating pastes in required patterns dependent upon the design can be applied on the bonding surfaces of various geometries including but not limited to: (i) a planar surface of a rectangular or a circular element (Planar Co-Bonding); (ii) a curved surface of a circular or annular element (Radial Co-Bonding); (iii) a spherical or a cubical surface of a spherical or cubical element (Spatial Co-Bonding).

FIG. 3a depicts planar surfaces types where co-bonding methods described herein can be applied to bond elements in various laminate shapes including rectangular 61 and circular 62 to obtain stacks in rectangular 64 and cylindrical 65 shapes. The bonded surfaces can have singular or plural annular regions 63 which are bonded from the planar surfaces to obtain stacked devices in tubular shapes 66.

FIG. 3b illustrates a radial stacking of elements 71, 72, 73 from their circular surfaces in radial direction to obtain radially stacked multilayer device 74. The embodiment shows radially stacked circular elements; however, the stacking laminates can be any shape as long as they have continuously matching side surfaces, such as a zig-zag, s-curved, etc.

FIG. 3c exemplifies a spatial stacking of elements 81, 82, 83 to obtain a spherical multi-layer device 84. Other than spherical shapes as shown in FIG. 3c, the spatially stacked elements can be in any shape as long as they have continuously matching alternating outside and inside surfaces.

While the invention has been disclosed with reference to a limited number of embodiments, it is apparent that variations and modification may be made therein, and it is therefore intended in the following claims to cover each such variation and modification as falls within the true spirit and scope of the invention. For example, while the method described herein has primarily been described as applicable to piezoelectric ceramic elements it may be broadly suitable for dielectric and ferroelectric elements as well.

The invention is illustrated by the following working example that is provided to exemplify an embodiment of the invention and is intended to be non-limiting.

### Working Example

The surfaces of two piezoelectric disks (25.38 mm outside diameter, 0.55 mm thickness, manufactured by Sunnytec (Suzhou) Co. Ltd and marked as Sunnytec-Soft as the material type) were cleaned by soaking the disks in an alcohol bath which was excited by an ultrasonic cleaner for 3 minutes.

The surfaces of the disks were dried in a 120° C. drying oven for 5 minutes.

One of the disks was placed on a screen printer, which uses 250 mesh count, 0.0016 wire diameter with 22.5 degree mesh angle with 11 micrometer emulsion thickness screen which has the desired electrode pattern's image centered on a 12×12 inch frame. ESL-599G conductive paste was spread over the screen while the disk was on the screen printer and printed through the screen.

ESL-4031-B isolating filler material was printed on the same disk with a syringe¹, so as to fill the electrode gaps, which were not covered by the conductive paste.

The printed disk was maintained in a dust-free chamber for 10 minutes for leveling.

The leveled printed disk was dried in a 120° C. drying oven for 15 minutes.

The blank (unprinted) disk was stacked on top of the printed disk while keeping the printed section in between and aligning the respective centers of the disks.

The stacked disks were placed on an alumina plate (99.6%), in order not to stick the stack to the chamber of the firing furnace. A 50 gram circular brass block (Alloy 385) having a 20 mm diameter was placed on the stack while the stack was on the alumina plate thereby creating a clamping pressure close to 1 kPa. While remaining on the alumina plate, the stack with the brass block resting atop it was placed in a firing furnace. The stack was subject to a 60 minutes of firing cycle in the firing furnace which increased from 25° C. to 550° C. in 25 minutes and remained at 550° C. for 15 minutes and decreased to 25° C. for 20 minutes thereby forming a 2 layer stacked disk structure.

It should be noted with respect to the above working example that a multilayer or “n-layer” stack can be obtained if the process described in the working example is applied to “n” piezoelectric elements.

It should further be noted that the following auxiliary steps described in paragraphs [0058] to [0061] below were performed for manufacturing a 2 layer device. However, these steps are unnecessary for the manufacture of device having more than 2 layers.

### Auxiliary Procedure for Working Example

Conductive paste was printed on the top surface of the stacked disk structure in the same manner as described above.

The stacked disk structure was maintained in a dust-free chamber for 10 minutes for leveling. The stacked disk structure was then dried in a 120° C. drying oven for 15 minutes.

The stacked disks were placed on an alumina plate (99.6%), in order not to stick the stack to the chamber of the firing furnace. While on the alumina plate, the stacked disks were was subject to a 60 minutes of firing cycle in the firing furnace which increased from 25° C. to 550° C. in 25 minutes and remained at 550° C. for 15 minutes and decreased to 25° C. for 20 minutes.

The process described in paragraphs [0058] to [0060] was repeated to generate an electrode pattern on the bottom surface of the stacked disks.

The working example continues with a polarization procedure for a parallel piezoelectric element stack.

The temperature of a silicon oil poling bath was raised to 130° C. The stacked disks were then fully immersed into the polling bath for about 10 minutes to allow the internal temperature of the stack to rise to approximately 130° C. prior to applying any voltage.

A 3.5 kV/mm DC electric field was applied to each 0.55 mm thick laminate or disk of the stack which were connected in parallel. In the case of a 2-layer stack, parallel connection means that the middle layer is grounded while the top and bottom surfaces are applied with a high DC voltage.

A 1.925 kV DC potential was applied to the stack for 20 minutes while the stack was immersed in 130° C. poling bath.

The example and alternative embodiments described above may be combined in a variety of ways with each other without departing from the invention.

As used above “substantially,” “generally,” “about” and other words of degree are relative modifiers intended to indicate permissible variation from the characteristic so modified. It is not intended to be limited to the absolute value or characteristic which it modifies but rather possessing more of the physical or functional characteristic than its opposite, and preferably, approaching or approximating such a physical or functional characteristic.

It will be appreciated that not all of the features, components and/or activities described above in the general description in relation to embodiments of the present disclosure or the examples are required, that a portion of a specific feature, component and/or activity may not be required, and that one or more further features, components and/or activities may be required, added or performed in addition to those described. Still further, the orders in which activities are listed are not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

After reading the specification, skilled artisans will appreciate that certain features are, for clarity, described herein in the context of separate embodiments, may also be provided in combination in a single embodiment. Conversely, various features that are, for brevity, described in the context of a single embodiment, may also be provided separately or in any sub-combination.

The Abstract of the Disclosure is provided to comply with Patent Law and is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all features of any of the disclosed embodiments. Thus, the following claims are incorporated into the Detailed Description, with each claim standing on its own as defining separately claimed subject matter.

We claim:

1. A method of manufacturing a multilayer piezoelectric device comprising:
forming a pattern of conductive paste on a surface of a first piezoelectric element;
applying isolating filler paste to the surface of the first piezoelectric element in a complementary pattern to the pattern of conductive paste such that substantially all of a surface area of the first piezoelectric element is covered by the isolating filler and the conductive paste;
drying the first piezoelectric element with the applied isolating filler paste and the conductive filler paste;
stacking a second piezoelectric element onto the first piezoelectric element such that a blank surface of the second piezoelectric element contacts the dried filler paste and dried conductive paste of the first piezoelectric element thereby forming a stacked structure;
firing the stacked structure for a sufficient time at a firing temperature sufficient to evaporate carriers and plasticizers present in the isolating and conductive pastes; and
polarizing the stacked structure.

2. The method of manufacturing the multilayer piezoelectric device of claim 1, wherein the isolating filler paste includes glass frit, organic solvent and plasticizer and is free from conducting metal hosts.

3. The method of manufacturing the multilayer piezoelectric device of claim 1, wherein drying includes subjecting the first piezoelectric element to a temperature of between 120° C. and 160° C. for a period of between 5 minutes and 15 minutes.

4. The method of manufacturing the multilayer piezoelectric device of claim 1, wherein the piezoelectric device is sintered and the firing temperature is maintained below a sintering temperature of the piezoelectric device.

5. The method of manufacturing the multilayer piezoelectric device of claim 1, wherein the firing temperature is maintained below a melting point of a host metal of the conductive paste.

6. The method of manufacturing the multilayer piezoelectric ceramic device of claim 1, wherein the surface of first piezoelectric device has a geometry selected from one of a planar geometry, a curved geometry, a spherical geometry.

7. A multilayer piezoelectric ceramic device produced according to the process of claim 1.

8. The method of manufacturing the multilayer piezoelectric ceramic device of claim 1, wherein a print thickness of the isolating filler material is within ±15% of a print thickness of the conductive paste.

9. The method of manufacturing the multilayer piezoelectric ceramic device of claim 1, wherein a print thickness of the isolating material is between about 40 μm and 10 μm.

10. The method of manufacturing the multilayer piezoelectric ceramic device of claim 1, wherein the isolating filler paste comprises a peel strength in a range of 75 to 100 lb/in².

11. The method of manufacturing the multilayer piezoelectric ceramic device of claim 1, wherein the isolating filler paste has a resistance greater than 10 Giga-ohm at 100 VDC.

12. A method of manufacturing a multilayer piezoelectric device comprising:
forming a pattern of conductive paste on a surface of a first piezoelectric element;
drying the first piezoelectric element with the applied conductive paste;
applying isolating filler paste to the surface of the dried first piezoelectric element in a complementary pattern to the pattern of conductive paste such that substantially all of a surface area of the first piezoelectric element is covered by the isolating filler paste;
drying the first piezoelectric element with the applied isolating filler paste;
stacking a second piezoelectric element onto the first piezoelectric element such that a blank surface of the second piezoelectric element contacts the dried filler paste and dried conductive paste of the first piezoelectric element thereby forming a stacked structure;
firing the stacked structure for a sufficient time at a firing temperature sufficient to evaporate carriers and plasticizers present in the isolating and conductive pastes; and
polarizing the stacked structure.

13. The method of manufacturing the multilayer piezoelectric device of claim 12, wherein the isolating filler paste includes glass frit, organic solvent and plasticizer and is free from conducting metal hosts.

14. The method of manufacturing the multilayer piezoelectric device of claim 12, wherein drying the first piezoelectric element with the applied conductive paste includes subjecting the first piezoelectric element to a temperature of between 120° C. and 160° C. for a period of between 5 minutes and 15 minutes.

15. The method of manufacturing the multilayer piezoelectric device of claim 12, wherein drying the first piezoelectric element with the applied isolating filler paste includes subjecting the first piezoelectric element to a temperature of between 120° C. and 160° C. for a period of between 5 minutes and 15 minutes.

16. The method of manufacturing the multilayer piezoelectric device of claim 1, wherein the piezoelectric device is sintered and the firing temperature is maintained below a sintering temperature of the piezoelectric device.

17. The method of manufacturing the multilayer piezoelectric ceramic device of claim 12, wherein the surface of first piezoelectric device has a geometry selected from one of a planar geometry, a curved geometry, a spherical geometry.

18. The method of manufacturing the multilayer piezoelectric ceramic device of claim 12, wherein a print thickness of the isolating material is between about 40 μm and 10 μm.

19. The method of manufacturing the multilayer piezoelectric device of claim 12, wherein the firing temperature is maintained below a melting point of a host metal of the conductive paste.
